(19) United States
(12) Patent Application Publication
(10) Pub. No.: US 2026/0165013 A1
(43) Pub. Date: Jun. 11, 2026

(54) Displays with Black Matrix Layers

(71) Applicant: Apple Inc., Cupertino, CA (US)

(72) Inventors: Xiao Li, Santa Clara, CA (US); Sukru Ekin Kocabas, Sunnyvale, CA (US); Yue Qu, Redwood City, CA (US); Shih-Chyuan Fan Jiang, San Jose, CA (US); Young Cheol Yang, Sunnyvale, CA (US); Yifan Zhang, Palo Alto, CA (US); Rui Liu, Los Altos, CA (US); Zhibing Ge, Sunnyvale, CA (US); Yuechen Wu, San Jose, CA (US); Kiseung Bang, Santa Clara, CA (US); Lei Lei, Cupertino, CA (US); Yishuai Xu, San Diego, CA (US); Yun Liu, Sunnyvale, CA (US); Yang Deng, San Jose, CA (US); Jean-Pierre S Guillou, La Jolla, CA (US); Lu Yan, Cupertino, CA (US); Ming E Tai, Santa Clara, CA (US); Paul C Kelley, San Francisco, CA (US); Salman Karbasi, San Jose, CA (US)

(21) Appl. No.: 19/373,311

(22) Filed: Oct. 29, 2025

Related U.S. Application Data
(60) Provisional application No. 63/729,178, filed on Dec. 6, 2024.

(51) Int. Cl. H10K 59/80; H10K 59/122; H10K 59/38; H10K 102/10

(52) U.S. Cl. CPC H10K 59/8792; H10K 59/122; H10K 59/38; H10K 59/80524; H10K 59/879; H10K 2102/101

(57) ABSTRACT

A display may include an array of pixels such as light-emitting diode pixels. The circular polarizer may be omitted from the display to increase efficiency. A polarizer-free display may use other non-polarizer techniques to mitigate reflections of ambient light and mitigate associated diffraction artifacts. The polarizer-free display may include a black matrix, color filter element, or pixel definition layer with tapered surfaces to make changes in reflectance associated with the subpixels more gradual. Anodes for the pixels may have non-planar upper surfaces. The pixels may have elliptical footprints with varying rotation angles arranged in a repeated unit cell. The display may overlap a sensor. In a portion of the display over the sensor, the black matrix may have openings between subpixels. The number of openings per unit area may vary across a transition region.

This application claims the benefit of U.S. provisional patent application No. 63/729,178, filed Dec. 6, 2024, which is hereby incorporated by reference herein in its entirety.

### BACKGROUND

Electronic devices often include displays. For example, cellular telephones and portable computers include displays for presenting information to users. An electronic device may have an organic light-emitting diode display based on organic-light-emitting diode pixels or a liquid crystal display based on liquid crystal pixels. Displays sometimes include a circular polarizer to mitigate reflections. However, the circular polarizer may decrease the efficiency of the display.

It is within this context that the embodiments herein arise.

### SUMMARY

A display may include a substrate, an array of light-emitting diodes on the substrate, a black matrix that is formed over the array of light-emitting diodes and that defines a plurality of openings, a plurality of color filter elements that are each formed in a respective opening of the plurality of openings, and an opaque pixel definition layer that defines light-emitting apertures for the array of light-emitting diodes. The opaque pixel definition layer may have tapered surfaces, the opaque pixel definition layer may have a first optical density, and the black matrix may have a portion with a second optical density that is greater than the first optical density.

A display may include a substrate, an array of pixels on the substrate comprising subpixels, blue subpixels, and red subpixels, a black matrix that defines elliptical openings for the green subpixels, blue subpixels, and red subpixels, and a plurality of color filter elements that are each formed in a respective elliptical opening of the elliptical openings. The elliptical openings for the green subpixels may have rotation angles that vary within a unit cell that is repeated across the array of pixels and the rotation angles for the green subpixels within the unit cell may be evenly distributed between 0 degrees and 180 degrees.

An electronic device may include a sensor and a display having an array of pixels and a black matrix. The array of pixels may include subpixels that emit light through the black matrix and the display may include a first portion that overlaps the sensor, a second portion, and a third portion that is interposed between the first and second portions. The subpixels in the first portion may be arranged in a repeated unit cell, the repeated unit cell in the first portion may include a first number of black matrix openings between adjacent subpixels, the subpixels in the second portion may be arranged in the repeated unit cell, the repeated unit cell in the second portion may include a second number of black matrix openings between adjacent subpixels, the subpixels in the third portion may be arranged in the repeated unit cell, the repeated unit cell in the third portion may include a third number of black matrix openings between adjacent subpixels, and the third number may be between the first number and the second number.

### BRIEF DESCRIPTION OF THE DRAWINGS

FIG. 1 is a schematic diagram of an illustrative electronic device having a display in accordance with some embodiments.

FIG. 2 is a schematic diagram of an illustrative display in accordance with some embodiments.

FIG. 3A is a cross-sectional side view of an illustrative display with a circular polarizer in accordance with some embodiments.

FIG. 3B is a cross-sectional side view of an illustrative display without a circular polarizer in accordance with some embodiments.

FIG. 4 is a cross-sectional side view of an illustrative polarizer-free display with color filter elements in accordance with some embodiments.

FIG. 5A is an illustrative reflectance profile showing the reflectance of red light across the footprint of a red subpixel with a red color filter element in accordance with some embodiments.

FIG. 5B is an illustrative reflectance profile showing the reflectance of red light across the footprint of a red subpixel with a red color filter element and a tapered component in accordance with some embodiments.

FIG. 6 is a cross-sectional side view of an illustrative polarizer-free display with a pixel definition layer having tapered surfaces in accordance with some embodiments.

FIG. 7 is a cross-sectional side view of an illustrative polarizer-free display with transparent metal patterning layers, a pixel definition layer having tapered surfaces, and an opaque metal layer in accordance with some embodiments.

FIG. 8 is a cross-sectional side view of an illustrative polarizer-free display with a pixel definition layer having tapered surfaces and a black matrix having tapered surfaces in accordance with some embodiments.

FIG. 9A is a cross-sectional side view of an illustrative polarizer-free display with color filter elements that each overlap a single microlens in accordance with some embodiments.

FIG. 9B is a cross-sectional side view of an illustrative polarizer-free display with color filter elements that each overlap a microlens array in accordance with some embodiments.

FIGS. 10A-10C are cross-sectional side views of illustrative anodes with convex upper surfaces in accordance with some embodiments.

FIGS. 11A-11C are cross-sectional side views of illustrative anodes with concave upper surfaces in accordance with some embodiments.

FIG. 12 is a top view of an illustrative display with subpixels having elliptical footprints in accordance with some embodiments.

FIG. 13 is a top view of an illustrative display with a repeating unit cell that includes a 4×4 grid of green subpixels having 16 unique rotation angles in accordance with some embodiments.

FIG. 14 is a top view of an illustrative display with a repeating unit cell that includes a 4×4 grid of green subpixels having 8 unique rotation angles in accordance with some embodiments.

FIG. 15 is a top view of an illustrative display with a repeating unit cell that includes a 6×6 grid of green subpixels having 18 unique rotation angles in accordance with some embodiments.

FIGS. 16A-16F are top views of illustrative displays showing possible positions for locally modified regions in accordance with some embodiments.

FIG. 17 is a top view of an illustrative display with black matrix openings in a locally modified region in accordance with some embodiments.

FIG. 18A is a cross-sectional side view of an illustrative display showing a black matrix without an opening between adjacent subpixels in accordance with some embodiments.

FIG. 18B is a cross-sectional side view of an illustrative display showing a black matrix with an opening between adjacent subpixels in accordance with some embodiments.

FIG. 19 is a top view of an illustrative display with a locally modified region having a transition region in accordance with some embodiments.

FIG. 20 is a top view of an illustrative display with locally modified regions having different numbers of black matrix openings per unit area in accordance with some embodiments.

FIG. 21A is an illustrative graph of the number of openings per unit cell as a function of position across the display in accordance with some embodiments.

FIG. 21B is an illustrative graph of the size of the openings in each unit cell as a function of position across the display in accordance with some embodiments.

FIG. 21C is an illustrative graph of the open area per unit cell as a function of position across the display in accordance with some embodiments.

FIG. 22A is a top view of an illustrative elliptical subpixel with a uniform black matrix pullback distance around its periphery in accordance with some embodiments.

FIG. 22B is a top view of an illustrative elliptical subpixel with a varying black matrix pullback distance around its periphery in accordance with some embodiments.

FIG. 23 is a top view of an illustrative pixel with a green elliptical subpixel that is orthogonal to red and blue elliptical subpixels in accordance with some embodiments.

### DETAILED DESCRIPTION

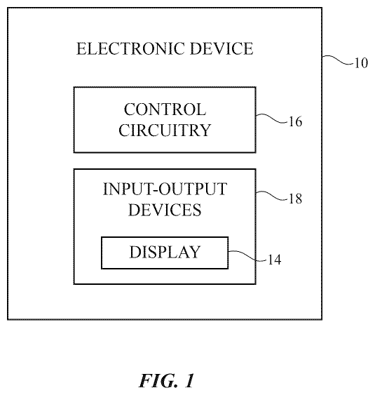

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wristwatch device, a pendant device, a headphone or earpiece device, an augmented reality (AR) headset and/or virtual reality (VR) headset, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment.

As shown in FIG. 1, electronic device 10 may have control circuitry 16. Control circuitry 16 may include storage and processing circuitry for supporting the operation of device 10. The storage and processing circuitry may include storage such as hard disk drive storage, nonvolatile memory (e.g., flash memory or other electrically-programmable-read-only memory configured to form a solid state drive), volatile memory (e.g., static or dynamic random-access-memory), etc. Processing circuitry in control circuitry 16 may be used to control the operation of device 10. The processing circuitry may be based on one or more microprocessors, microcontrollers, digital signal processors, baseband processors, power management units, audio chips, application specific integrated circuits, etc.

Input-output circuitry in device 10 such as input-output devices 18 may be used to allow data to be supplied to device 10 and to allow data to be provided from device 10 to external devices. Input-output devices 18 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input-output devices 18 and may receive status information and other output from device 10 using the output resources of input-output devices 18.

Input-output devices 18 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements.

Control circuitry 16 may be used to run software on device 10 such as operating system code and applications. During operation of device 10, the software running on control circuitry 16 may display images on display 14.

Display 14 may be an organic light-emitting diode display, a display formed from an array of discrete light-emitting diodes each formed from a crystalline semiconductor die, or any other suitable type of display. Configurations in which the pixels of display 14 include light-emitting diodes are sometimes described herein as an example. This is, however, merely illustrative. Any suitable type of display may be used for device 10, if desired (e.g., a liquid crystal display).

In some cases, electronic device 10 may be a wristwatch device. Display 14 of the wristwatch device may be positioned in a housing. A wristwatch strap may be coupled to the housing.

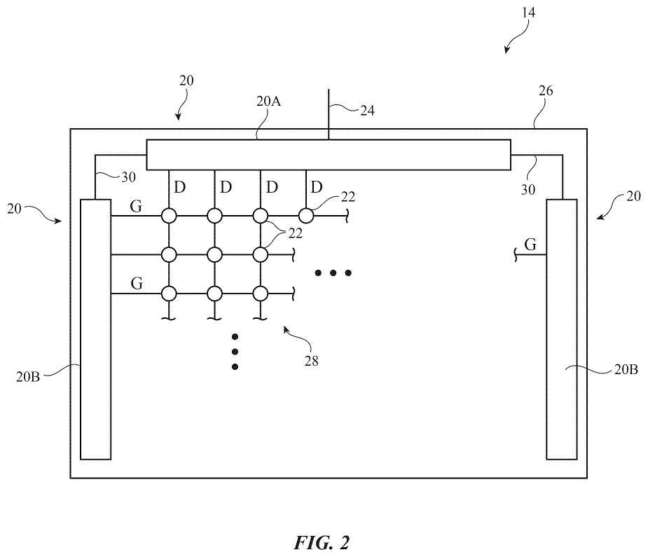

FIG. 2 is a diagram of an illustrative display. As shown in FIG. 2, display 14 may include layers such as substrate layer 26. Substrate layers such as layer 26 may be formed from rectangular planar layers of material or layers of material with other shapes (e.g., circular shapes or other shapes with one or more curved and/or straight edges). The substrate layers of display 14 may include glass layers, polymer layers, composite films that include polymer and inorganic materials, metallic foils, etc.

Display 14 may have an array of pixels 22 for displaying images for a user such as subpixel array 28. Pixels 22 in array 28 may be arranged in rows and columns. The edges of array 28 (sometimes referred to as active area 28) may be straight or curved (i.e., each row of pixels 22 and/or each column of pixels 22 in array 28 may have the same length or may have a different length). There may be any suitable number of rows and columns in array 28 (e.g., ten or more, one hundred or more, or one thousand or more, etc.). Each pixel in display 14 may include subpixels of different colors. As an example, display 14 may include red subpixels, green subpixels, and blue subpixels. If desired, a backlight unit may provide backlight illumination for display 14.

Display driver circuitry 20 may be used to control the operation of pixels 22. Display driver circuitry 20 may be formed from integrated circuits, thin-film transistor circuits, and/or other suitable circuitry. Illustrative display driver circuitry 20 of FIG. 2 includes display driver circuitry 20A and additional display driver circuitry such as gate driver circuitry 20B. Gate driver circuitry 20B may be formed along one or more edges of display 14. For example, gate driver circuitry 20B may be arranged along the left and right sides of display 14 in an inactive area of the display as shown in FIG. 2. Gate driver circuitry 20B may include gate drivers and emission drivers.

As shown in FIG. 2, display driver circuitry 20A (e.g., one or more display driver integrated circuits, thin-film transistor circuitry, etc.) may contain communications circuitry for communicating with system control circuitry over signal path 24. Path 24 may be formed from traces on a flexible printed circuit or other cable. The control circuitry may be located on one or more printed circuits in electronic device 10. During operation, the control circuitry (e.g., control circuitry 16 of FIG. 1) may supply circuitry such as a display driver integrated circuit in circuitry 20 with image data for images to be displayed on display 14. Display driver circuitry 20A of FIG. 2 is located at the top of display 14. This is merely illustrative. Display driver circuitry 20A may be located at both the top and bottom of display 14 or in other portions of device 10.

To display the images on pixels 22, display driver circuitry 20A may supply corresponding image data to data lines D (e.g., vertical signal lines) while issuing control signals to supporting display driver circuitry such as gate driver circuitry 20B over signal paths 30. With the illustrative arrangement of FIG. 2, data lines D run vertically through display 14 and are associated with respective columns of pixels 22. During compensation operations, column driver circuitry 20 may use paths such as data lines D to supply a reference voltage.

Gate driver circuitry 20B (sometimes referred to as gate line driver circuitry or horizontal control signal circuitry) may be implemented using one or more integrated circuits and/or may be implemented using thin-film transistor circuitry on substrate 26. Horizontal control lines G (sometimes referred to as gate lines, scan lines, emission control lines, etc.) run horizontally through display 14. Each gate line G is associated with a respective row of pixels 22. If desired, there may be multiple horizontal control lines such as gate lines G associated with each row of pixels. Individually controlled and/or global signal paths in display 14 may also be used to distribute other signals (e.g., power supply signals, etc.). The number of horizontal signal lines in each row may be determined by the number of transistors in the display pixels 22 that are being controlled independently by the horizontal signal lines. Display pixels of different configurations may be operated by different numbers of control lines, data lines, power supply lines, etc.

Gate driver circuitry 20B may assert control signals on the gate lines G in display 14. For example, gate driver circuitry 20B may receive clock signals and other control signals from circuitry 20A on paths 30 and may, in response to the received signals, assert a gate line signal on gate lines G in sequence, starting with the gate line signal G in the first row of pixels 22 in array 28. As each gate line is asserted, data from data lines D may be loaded into a corresponding row of pixels. In this way, control circuitry such as display driver circuitry 20A and 20B may provide pixels 22 with signals that direct pixels 22 to display a desired image on display 14. Each pixel may have multiple subpixels that have a light-emitting diode and circuitry (e.g., thin-film circuitry on substrate 26) that respond to the control and data signals from display driver circuitry 20.

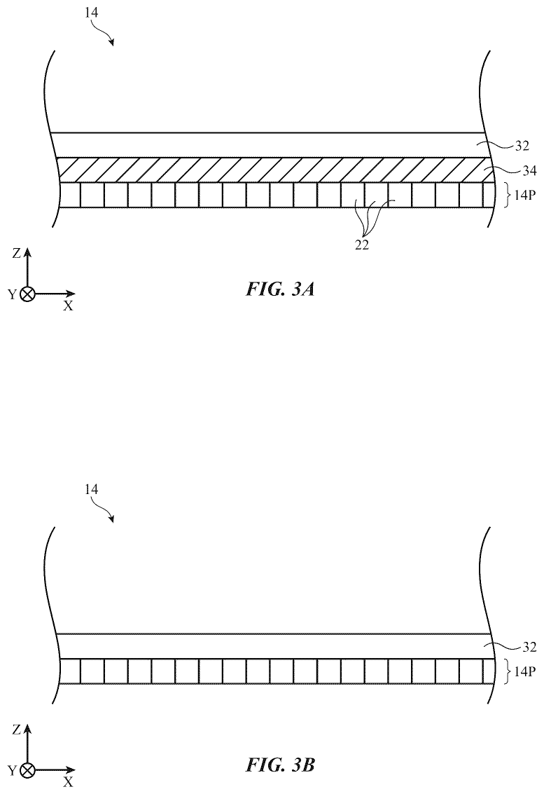

Some displays may include a circular polarizer to mitigate reflections of ambient light. As shown in FIG. 3A, display 14 includes a display panel 14P with an array of pixels 22. Display panel 14P may be an organic light-emitting diode display panel, a display panel formed from an array of discrete light-emitting diodes each formed from a crystalline semiconductor die, a liquid crystal display panel, or any other suitable type of display. The display panel 14P is covered by a display cover layer 32. Display cover layer 32 may be a transparent material that forms an outer surface of the display (and device 10). The display cover layer 32 may protect the underlying display panel from damage during operation of the device. The display cover layer 32 may be formed from plastic, glass, sapphire, or any other desired material.

In FIG. 3A, a circular polarizer 34 is interposed between the display panel 14P and the display cover layer 32. Circular polarizer 34 may include a linear polarizer and a quarter wave plate. The circular polarizer serves to mitigate undesired reflections of ambient light off of display panel 14P. When ambient light passes in the negative Z-direction through display cover layer 32 and circular polarizer 34, the light becomes circularly polarized. The light may subsequently reflect off of reflective layers of display panel 14P (e.g., anodes for the pixels 22 in display panel 14P). The reflected light (now traveling in the positive Z-direction) has the opposite circular polarization and is subsequently absorbed by the circular polarizer 34. The circular polarizer 34 therefore effectively prevents ambient light reflections off of display panel 14P, improving contrast in display 14.

Although effective at mitigating ambient light reflections, circular polarizer 34 reduces the efficiency of display 14. The display light emitted by pixels 22 passes through circular polarizer 34 when exiting the display. This reduces the intensity of the display light exiting display 14.

To improve the efficiency of the display, circular polarizer 34 may be omitted from the display. FIG. 3B is a cross-sectional side view of a display of this type. As shown, display cover layer 32 is formed over display panel 14P without an intervening circular polarizer. This type of display may sometimes be referred to as a polarizer-free display, a circular-polarizer-free display, a polarizer-free OLED display, circular-polarizer-free OLED display etc.

Omitting the circular polarizer in display 14 increases the efficiency of the display. Additionally, omitting the circular polarizer in display 14 may help align the neutral stress plane of the display with sensitive components in display panel 14P (e.g., the thin-film transistor circuitry in the display panel). This makes the display more robust to bending and folding. Yet another advantage of omitting the circular polarizer is improved efficiency/performance for input-output components that operate through the display. For example, an optical sensor may sense light that passes through the display. Omitting the circular polarizer increases the signal-to-noise ratio for the optical sensor.

The polarizer-free display may use other techniques to mitigate artifacts caused by reflections of ambient light and preserve a high contrast for the display.

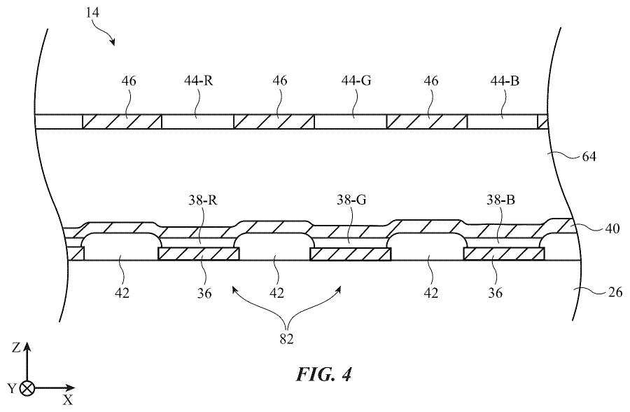

FIG. 4 is a side view of an illustrative polarizer-free display. As shown in FIG. 4, the display includes organic light-emitting diode subpixels 82 on substrate 26. Each OLED subpixel 82 includes an electrode (anode) 36, OLED layers 38, and a common electrode (cathode) 40. The OLED layers 38 may include OLED layers such as a hole injection layer, a hole transport layer, an emissive layer, an electron transport layer, an electronic injection layer, an electron blocking layer, a charge generation layer, and/or a hole blocking layer. Each subpixel may include a single diode or a tandem diode. A common cathode 40 is formed over the array of pixels. The cathode may be formed as a blanket layer across the entire array and serves as the cathode electrode for each subpixel in the display. The OLED layers 38 are interposed between the cathode 40 and respective anodes 36. Each subpixel may have an emissive layer of a selected color (e.g., red, green, or blue) as one of its OLED layers 38. As shown in FIG. 4, a first subpixel includes red OLED layers 38-R that are configured to emit red light, a second subpixel includes green OLED layers 38-G that are configured to emit green light, and a third subpixel includes blue OLED layers 38-B that are configured to emit blue light.

Display 14 also includes a pixel definition layer 42. The pixel definition layer 42 may be formed from a dielectric material and may be used to define light-emitting apertures for each subpixel. The OLED layers 38 and corresponding anodes 36 are formed in the apertures defined by the pixel definition layer 42. Pixel definition layer 42 may optionally be opaque.

As shown in FIG. 4, display 14 also includes color filter elements 44 that are formed within openings in a grid of black matrix 46 (sometimes referred to as black masking layer 46, opaque masking layer 46, etc.). Each color filter element 44 may overlap a respective subpixel 82 that emits light at a given color (wavelength). Each color filter element 44 may transmit light at the given wavelength for its overlapped subpixel while blocking light for other wavelengths. For example, each red OLED subpixel 82 is overlapped by a red color filter 44-R that transmits red light while blocking blue light and green light. Each green OLED subpixel 82 is overlapped by a green color filter 44-G that transmits green light while blocking blue light and red light. Each blue OLED subpixel 82 is overlapped by a blue color filter 44-B that transmits blue light while blocking red light and green light.

The color filter elements 44 allow light from the display subpixels to pass through to the viewer. Therefore, the display performance is not negatively impacted by the color filter elements. Simultaneously, the color filter elements 44 block much of the ambient light from being reflected. Each blue color filter element blocks red and green ambient light from being reflected, each red color filter element blocks blue and green ambient light from being reflected, and each green color filter element blocks red and blue ambient light from being reflected. Each color filter element may therefore block approximately ⅔ of incident ambient light.

Black matrix 46 may be formed from any desired material that absorbs light. Black matrix 46 may reflect less than 20% of incident light, less than 10% of incident light, less than 5% of incident light, less than 3% of incident light, less than 1% of incident light, etc. Black matrix 46 may transmit less than 20% of incident light, less than 10% of incident light, less than 5% of incident light, less than 3% of incident light, less than 1% of incident light, etc. Black matrix 46 may absorb more than 50% of incident light, more than 75% of incident light, more than 90% of incident light, more than 95% of incident light, etc. Black matrix 46 blocks ambient light from reflecting off the display.

In FIG. 4, one or more planarization layers 64 may be formed between cathode 40 and color filter elements 44 and black matrix 46. The one or more planarization layers 64 has first and second opposing sides. Cathode 40 (and the OLED subpixels 82) is formed on the first side whereas color filter elements 44 and black matrix 46 are formed on the second side. The one or more planarization layers 64 may be formed from, for example, organic dielectric material that is deposited using inkjet printing (IJP). The planarization layer(s) 64 may therefore sometime be referred to as dielectric layer(s) 64, IJP layer(s) 64, organic layer(s) 64, etc. Color filter elements 44 and black matrix 46 may be formed in direct contact with an upper surface of IJP layer(s) 64.

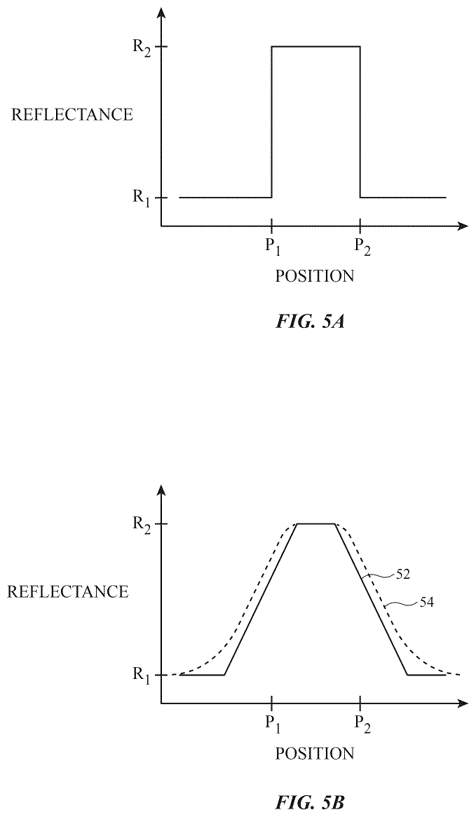

The display of FIG. 4 may have diffraction artifacts associated with reflections of ambient light in display 14. The diffraction artifacts may be at least partially caused by the step change in reflectivity across the display. FIG. 5A shows the reflectance of red light across the footprint of a red subpixel with a red color filter element. The red light is not blocked by the red color filter element. Accordingly, ambient red light passes through the red color filter element, reflects off an underlying reflective layer (e.g., anode 36), and passes through the red color filter element towards the viewer. In the arrangement of FIG. 4, the black matrix 46 has vertical edges. Accordingly, as shown by the reflectance profile in FIG. 5A, the reflectance has a step change between minimum reflectance R₁ in areas overlapped by the black matrix and maximum reflectance R₂ in areas not overlapped by the black matrix (e.g., between positions P₁ and P₂). This type of reflection profile may be associated with strong diffraction artifacts.

To mitigate diffraction artifacts, one or more components within display 14 may have a varying thickness (and corresponding tapered surface) to cause the reflectance profile to gradually change between R₁ and R₂. FIG. 5B shows the reflectance of red light across the footprint of a red subpixel with a red color filter element and a tapered component. As shown by the reflectance profile in FIG. 5B, similar to as in FIG. 5A, has an associated minimum reflectance R₁ in an area overlapped by the black matrix and maximum reflectance R₂ in an area not overlapped by the black matrix. Between R₁ and R₂, the reflectance may change gradually. This gradual change in the reflectance profile may mitigate diffraction artifacts in ambient light reflected off display 14. The gradual change in reflectance between R₁ and R₂ may be linear (as with profile 52) or non-linear (as with profile 54).

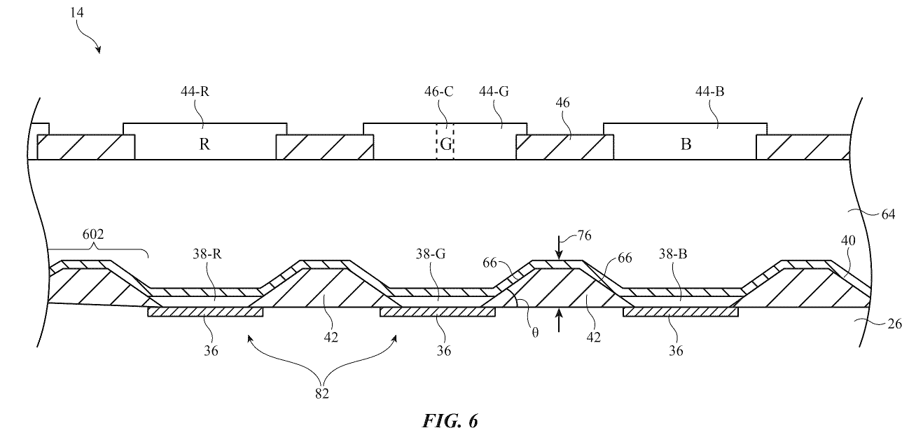

FIG. 6 is a side view of an illustrative display with an opaque pixel definition layer having a tapered surface. As shown in FIG. 6, pixel definition layer 42 has tapered surfaces 66 where the thickness of the pixel definition layer gradually changes. Pixel definition layer 42 may be formed from an opaque material (e.g., a black material). The pixel definition layer 42 may have a maximum thickness 76 in a portion of the pixel definition layer between adjacent subpixels (e.g., at a point equidistance between the two closest subpixels). The thickness of the pixel definition layer may gradually decrease from maximum thickness 76 to a thickness of 0 at a point that overlaps a respective subpixel 82. The thickness of the pixel definition layer therefore decreases with decreasing separation from a center of a respective subpixel 82. The thickness of the pixel definition layer may decrease continuously and monotonically across tapered surface 66.

The transmittance of light through the pixel definition layer may increase with decreasing thickness of the pixel definition layer. Through the maximum thickness of the pixel definition layer, the transmittance through the pixel definition layer (e.g., the minimum transmittance) may be less than 40%, less than 20%, less than 10%, less than 5%, less than 3%, etc. At the edge of the pixel definition layer where the thickness of the pixel definition layer is 0, the transmittance through the pixel definition layer (e.g., the maximum transmittance) may be 100% (since there is no pixel definition layer material to block the light). At an intermediate point between the maximum thickness portion and the edge (e.g., where the thickness is greater than 0 but less than the maximum thickness), the transmittance through the pixel definition layer may be 50%. The transmittance may change gradually between the minimum and maximum values as the thickness gradually decreases due to tapered surface 66. This type of transmittance profile may cause a subpixel to have one of the reflectance profiles of FIG. 5B, desirably mitigating diffraction artifacts associated with reflections of ambient light.

Tapered surfaces 66 may have an associated taper angle θ relative to the upper surface of substrate 26 and anodes 36. Taper angle θ may have any desired magnitude (e.g., less than 50 degrees, less than 45 degrees, less than 40 degrees, less than 35 degrees, less than 30 degrees, less than 25 degrees, greater than 10 degrees, greater than 20 degrees, greater than 25 degrees, between 20 degrees and 30 degrees, between 10 degrees and 50 degrees, between 41 and 49 degrees, etc.).

In the arrangement of FIG. 6, cathode 40 may be formed from a transparent conductive oxide (TCO) material. The cathode of FIG. 6 may have a transparency that is greater than 60%, greater than 70%, greater than 80%, greater than 85%, greater than 90%, etc. The cathode may have a reflectance that is less than 30%, less than 20%, less than 15%, less than 10%, less than 5%, etc.

In the arrangement of FIG. 6, the opaque pixel definition layer 42 may have a lower optical density (OD) than black matrix 46. Optical density may have the units μm⁻¹, where the transmission percentage is determined by the formula 1/(10^{OD}). As specific examples, black matrix 46 may have an OD of 1.5 μm⁻¹ whereas opaque pixel definition layer 42 may have an OD of 0.5 μm⁻¹. Transmission through a 1 micron thick black matrix is therefore 1/(10^{1.5})=3.2%. Transmission through a 1 micron thick opaque pixel definition layer is therefore 1/(10^{0.5})=31.6%. The OD of opaque pixel definition layer 42 may be lower than the OD of black matrix 46 by at least 0.2 μm⁻¹, at least 0.5 μm⁻¹, at least 0.8 μm⁻¹, at least 1.0 μm⁻¹, at least 1.2 μm⁻¹, etc. The OD of opaque pixel definition layer 42 may be less than 0.7 μm⁻¹, less than 0.5 μm⁻¹, less than 0.4 μm⁻¹, less than 0.3 μm⁻¹, etc. The OD of black matrix 46 may be greater than 1.0 μm⁻¹, greater than 1.3 μm⁻¹, greater than 1.5 μm⁻¹, etc.

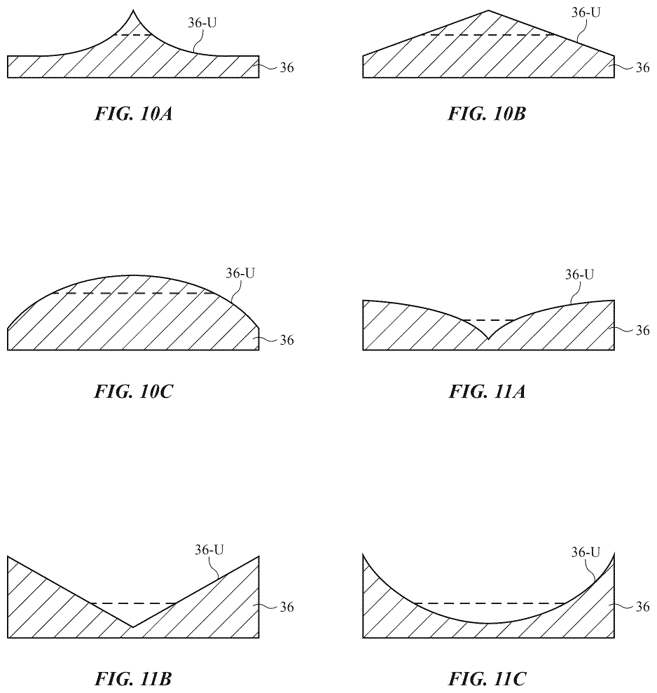

FIG. 6 further shows how a black matrix opening may optionally be ring-shaped. In FIG. 6, the black matrix defining an opening for green color filter element 44-G may have an optional central portion 46-C. When central portion 46-C is included, the opening in the black matrix for the subpixel is a ring-shaped opening (sometimes referred to as an annular opening). A ring-shaped black matrix opening may help block ambient light reflections, particularly when paired with a concave anode of the type shown in FIGS. 11A-11C, as is discussed later in additional detail.

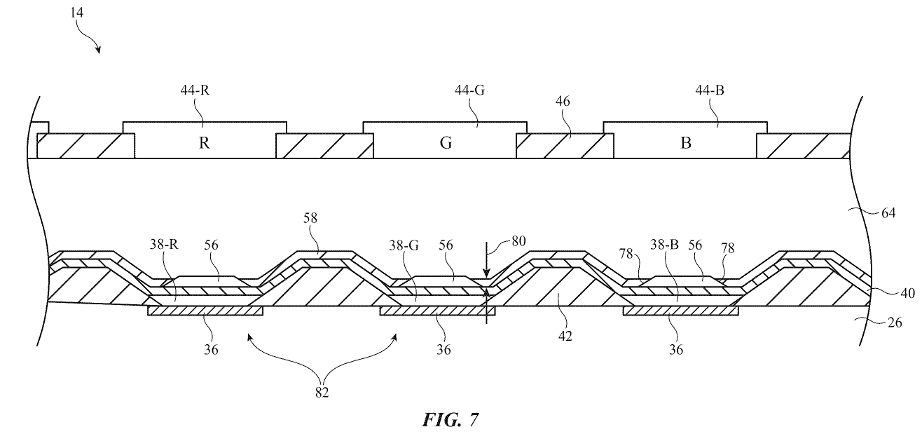

FIG. 7 is a side view of an illustrative display with an opaque metal layer having a tapered surface. In the example of FIG. 7, each subpixel 82 includes a metal patterning layer 56 that overlaps the light-emitting area of that subpixel. The metal patterning layer 56 may be formed using a fine metal mesh and evaporation. The metal patterning layer 56 therefore has tapered surfaces at a non-zero, non-orthogonal angle relative to the upper surfaces of substrate 26 and anodes 36. The metal patterning layer 56 may have a transparency that is greater than 70%, greater than 80%, greater than 90%, greater than 95%, greater than 98%, etc.

After the metal patterning layer 56 is formed over each subpixel, a dark metal layer 58 may be deposited over cathode 40 and the metal patterning layers 56. The metal patterning layers 56 may repel the dark metal layer 58 such that the dark metal layer does not overlap a central portion of each metal patterning layer and conforms to the tapered edge surfaces of each metal patterning layer. Metal patterning layers 56 may be formed from a dielectric or conductive material that repels metal layer 58. The dark metal layer 58 therefore has tapered surfaces 78 that laterally surround the light-emitting aperture for each subpixel. The tapered surfaces may have a taper angle relative to the upper surface of substrate 26 and/or anodes 36 that is less than 45 degrees, less than 40 degrees, less than 35 degrees, less than 30 degrees, less than 25 degrees, greater than 10 degrees, greater than 20 degrees, greater than 25 degrees, between 20 degrees and 30 degrees, between 10 degrees and 50 degrees, etc. The OD of metal layer 58 may be less than 1.0 μm⁻¹, less than 1.3 μm⁻¹, less than 1.5 μm⁻¹, less than 0.7 μm⁻¹, less than 0.5 μm⁻¹, less than 0.4 μm⁻¹, less than 0.3 μm⁻¹, greater than 1.0 μm⁻¹, greater than 1.3 μm⁻¹, greater than 1.5 μm⁻¹, greater than 0.7 μm⁻¹, greater than 0.5 μm⁻¹, greater than 0.4 μm⁻¹, greater than 0.3 μm⁻¹, etc.

The thickness of the dark metal layer 58 may gradually decrease from maximum thickness 80 to a thickness of 0 at a point that overlaps a respective subpixel 82. The thickness of the dark metal layer therefore decreases with decreasing separation from a center of a respective subpixel 82. The thickness of the dark metal layer may decrease continuously and monotonically across tapered surface 78.

The transmittance of light through the dark metal layer may increase with decreasing thickness of the pixel definition layer. Through the maximum thickness of the dark metal layer, the transmittance through the dark metal layer (e.g., the minimum transmittance) may be less than 40%, less than 20%, less than 10%, less than 5%, less than 3%, etc. At the edge of the dark metal layer where the thickness of the dark metal layer is 0, the transmittance through the dark metal layer (e.g., the maximum transmittance) may be 100% (since there is no dark metal layer material to block the light). At an intermediate point between the maximum thickness portion and the edge (e.g., where the thickness is greater than 0 but less than the maximum thickness), the transmittance through the dark metal layer may be 50%. The transmittance may change gradually between the minimum and maximum values as the thickness gradually decreases due to tapered surface 78. This type of transmittance profile may cause a subpixel to have one of the reflectance profiles of FIG. 5B, desirably mitigating diffraction artifacts associated with reflections of ambient light. The arrangement of FIG. 7 may accommodate a cathode formed from a non-TCO material that has a transparency that is less than 80%, less than 70%, less than 60%, etc.

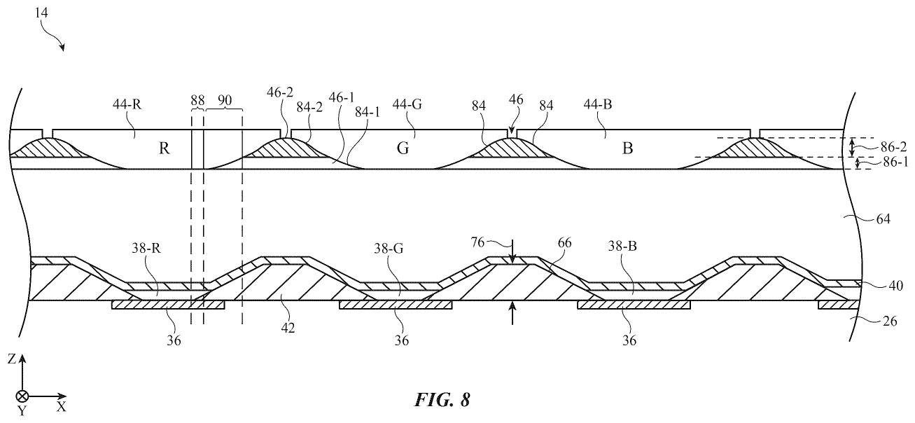

FIG. 8 is a side view of an illustrative display with an opaque pixel definition layer and a black matrix having tapered surfaces. As shown in FIG. 8, pixel definition layer 42 may have the same arrangement as in FIG. 6. Additionally, black matrix 46 may have tapered surfaces 84. Black matrix 46 also includes two portions with different optical densities. Black matrix 46 includes a first portion 46-1 with a first optical density and a second portion 46-2 with a second, different optical density. Portion 46-1 (with the lower optical density) may be interposed between pixel definition layer 42 and portion 46-2 (with the higher optical density). Portion 46-1 has portions that extend past the edges of portion 46-2. In other words, the footprint of portion 46-1 is larger than the footprint of portion 46-2. Portion 46-1 is referred to as having tapered surfaces 84-1 and portion 46-2 is referred to as having tapered surfaces 84-2.

Tapered surface 84-1 may have a taper angle of any desired magnitude (e.g., less than 45 degrees, less than 40 degrees, less than 35 degrees, less than 30 degrees, less than 25 degrees, greater than 10 degrees, greater than 20 degrees, greater than 25 degrees, between 20 degrees and 30 degrees, between 10 degrees and 50 degrees, etc.). Tapered surface 84-2 may have a taper angle of any desired magnitude (e.g., less than 45 degrees, less than 40 degrees, less than 35 degrees, less than 30 degrees, less than 25 degrees, greater than 10 degrees, greater than 20 degrees, greater than 25 degrees, between 20 degrees and 30 degrees, between 10 degrees and 50 degrees, etc.).

The OD of opaque pixel definition layer 42 in FIG. 8 may be less than 0.7 μm⁻¹, less than 0.5 μm⁻¹, less than 0.4 μm⁻¹, less than 0.3 μm⁻¹, greater than 0.3 μm⁻¹, etc. The OD of black matrix portion 46-1 in FIG. 8 may be less than 0.7 μm⁻¹, less than 0.5 μm⁻¹, less than 0.4 μm⁻¹, less than 0.3 μm⁻¹, greater than 0.3 μm⁻¹, etc. The OD of black matrix portion 46-2 in FIG. 8 may be greater than 1.0 μm⁻¹, greater than 1.3 μm⁻¹, greater than 1.5 μm⁻¹, less than 2.0 μm⁻¹, etc. The OD of black matrix portion 46-1 may be lower than the OD of black matrix portion 46-2 by at least 0.2 μm⁻¹, at least 0.5 μm⁻¹, at least 0.8 μm⁻¹, at least 1.0 μm⁻¹, at least 1.2 μm⁻¹, etc.

The thickness of black matrix portion 46-1 may gradually decrease from maximum thickness 86-1 to a thickness of 0 at a point that overlaps anode 36. The thickness of the black matrix portion 46-1 therefore decreases with decreasing separation from a center of a respective subpixel 82. The thickness of the black matrix portion 46-1 may decrease continuously and monotonically across tapered surface 84-1.

The thickness of black matrix portion 46-2 may gradually decrease from maximum thickness 86-2 to a thickness of 0 at a point that overlaps black matrix portion 46-1. The thickness of the black matrix portion 46-2 therefore decreases with decreasing separation from a center of a respective subpixel 82. The thickness of the black matrix portion 46-2 may decrease continuously and monotonically across tapered surface 84-2.

Each subpixel therefore has a first region 88 that is vertically overlapped (e.g., in the Z-direction) by pixel definition layer 42 but not by any portion of black matrix 46. There is therefore a first reflectance profile in this region that is based on the optical density of pixel definition layer 42. Each subpixel also has a second region 90 that is vertically overlapped (e.g., in the Z-direction) by pixel definition layer 42 and black matrix portion 46-1. There is therefore a second reflectance profile in this region that is based on the optical density of pixel definition layer 42 and black matrix portion 46-1. This type of arrangement may help achieve a smoother reflectance transition which desirable mitigates diffractive artifacts. The arrangement of FIG. 8 may accommodate a cathode formed from a non-TCO material that has a transparency that is less than 80%, less than 70%, less than 60%, etc.

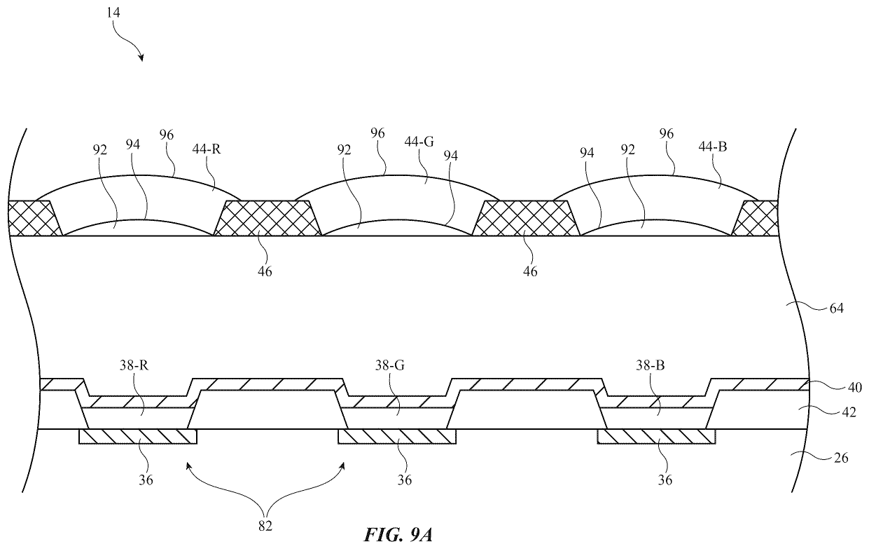

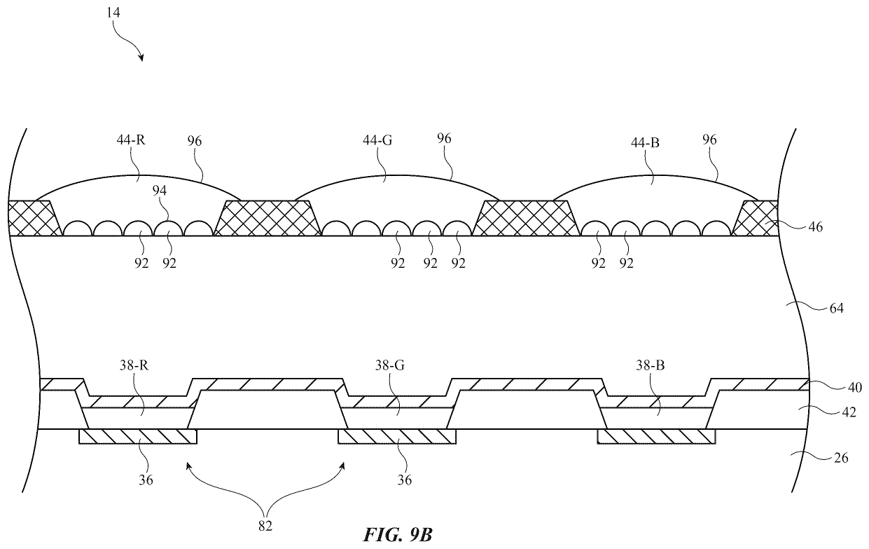

To mitigate ambient light reflections in display 14, each subpixel 82 may include one or more microlenses. FIGS. 9A and 9B are cross-sectional side views of displays with one or more microlenses. In the example of FIG. 9A, each subpixel 82 includes a single respective microlens 92. Each microlens may have an upper surface 94 with convex curvature. FIG. 9A further shows how each color filter element 44 may optionally have an upper surface 96 with convex curvature.

Each microlens is overlapped by a respective color filter element. Each microlens may have a refractive index that is less than the refractive index of its overlapping color filter element (e.g., by at least 0.1, at least 0.2, at least 0.3, at least 0.4, at least 0.5, etc.). Each microlens may have a refractive index that is less than the refractive index of the adjacent planarization layer(s) 64 (e.g., by at least 0.1, at least 0.2, at least 0.3, at least 0.4, at least 0.5, etc.). With this type of arrangement, the microlens may spread incoming incident light and reduce the amount of ambient light that reflects off anode 36.

Each microlens may be transparent to one or more wavelengths of incident light. In one possible arrangement, each microlens is transparent to visible light (e.g., the microlens does not perform any color filtering). In another possible arrangement, each microlens is more transparent to some colors of visible light than other colors of visible light (e.g., the microlens also serves as a color filter). As an example, a microlens that is overlapped by a blue color filter may transmit blue light while blocking red and green light, a microlens that is overlapped by a green color filter may transmit green light while blocking red and blue light, and a microlens that is overlapped by a red color filter may transmit red light while blocking blue and green light.

In the example of FIG. 9A, each subpixel includes exactly one microlens. This example is merely illustrative. As shown in FIG. 9B, a single subpixel may optionally include multiple microlenses 92. Each microlens in FIG. 9B may have any of the properties discussed in connection with FIG. 9A. Each subpixel may include more than one microlens, more than four microlens, more than ten microlens, more than sixteen microlens, more than twenty-five microlens, etc. The microlenses for a given subpixel may be arranged in an array of rows and columns.

To mitigate diffractive artifacts associated with ambient light reflections, display 14 may include non-planar anodes. FIGS. 10A-10C are cross-sectional side views of illustrative anodes with convex upper surfaces. In each one of FIGS. 10-10C, the maximum anode thickness is at the center of the anode and the minimum anode thickness is at the outer edges of the anode. In FIG. 10A, upper surface 36-U of anode 36 follows a profile proportional to X^{Y}, where Y is less than 1 (e.g., Y may be equal to 0.5) and X is position along the cross-section of the anode. A given half of a cross-section of the anode of FIG. 10A is concave. In FIG. 10B, upper surface 36-U of anode 36 follows a profile proportional to X¹, where X is position along the cross-section of the anode. In other words, the upper surface is cone-shaped. A given half of a cross-section of the anode of FIG. 10B is planar. In FIG. 10C, upper surface 36-U of anode 36 follows a profile proportional to X^{Y}, where Y is greater than 1 (e.g., Y may be equal to 1.5) and X is position along the cross-section of the anode. A given half of a cross-section of the anode of FIG. 10C is convex. These examples of profiles for the convex upper surface are merely illustrative. In general, the upper surface may have any desired convex profile (e.g., spherical dome, ripple, etc.).

FIGS. 11A-11C are cross-sectional side views of illustrative anodes with concave upper surfaces. In each one of FIGS. 11-11C, the minimum anode thickness is at the center of the anode and the maximum anode thickness is at the outer edges of the anode. In FIG. 11A, upper surface 36-U of anode 36 follows a profile proportional to X^{Y}, where Y is less than 1 (e.g., Y may be equal to 0.5) and X is position along the cross-section of the anode. A given half of a cross-section of the anode of FIG. 11A is convex. In FIG. 11B, upper surface 36-U of anode 36 follows a profile proportional to X¹, where X is position along the cross-section of the anode. In other words, the upper surface is cone-shaped. A given half of a cross-section of the anode of FIG. 11B is planar. In FIG. 11C, upper surface 36-U of anode 36 follows a profile proportional to X^{Y}, where Y is greater than 1 (e.g., Y may be equal to 1.5) and X is position along the cross-section of the anode. A given half of a cross-section of the anode of FIG. 11C is concave. These examples of profiles for the concave upper surface are merely illustrative. In general, the upper surface may have any desired concave profile (e.g., spherical dome, ripple, etc.).

The concave anodes of FIGS. 11A-11C may be used in subpixels with ring-shaped black matrix openings of the type shown in FIG. 6. With this arrangement, the concave anodes may focus ambient light reflections on the central portion 46-C of the black matrix, thus mitigating ambient light reflections that are viewable by a user of electronic device 10.

In each one of FIGS. 10A-10C and 11A-11C, the upper surface is symmetrical. In each one of FIGS. 10A-10C and 11A-11C, there may be an optional planar central portion to upper surface 36-U as marked by the dashed lines in FIGS. 10A-10C and 11A-11C. The planar central portion (which has the maximum thickness in FIGS. 10A-10C and the minimum thickness in FIGS. 11A-11C) may improve diffraction artifact mitigation, manufacturing cost, and/or manufacturing complexity.

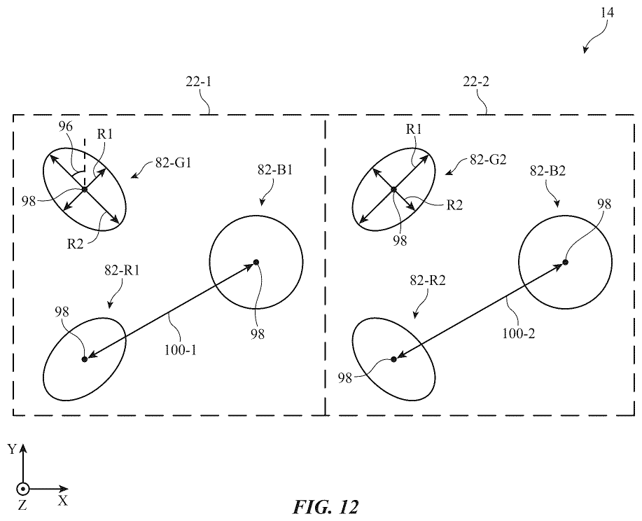

FIG. 12 is a top view of a display with different pixels having different subpixel footprints. A first pixel 22-1 includes a first green subpixel 82-G1, a first blue subpixel 82-B1, and a first red subpixel 82-R1. A second pixel 22-2 includes a second green subpixel 82-G2, a second blue subpixel 82-B2, and a second red subpixel 82-R2. Each subpixel has a respective center 98.

As shown in FIG. 12, subpixel 82-G1 has first elliptical footprint whereas subpixel 82-G2 has a second, different elliptical footprint. The green subpixels in pixels 22-1 and 22-2 therefore have different, unique elliptical footprints. Subpixel 82-B1 has first elliptical footprint whereas subpixel 82-B2 has a second, different elliptical footprint. The blue subpixels in pixels 22-1 and 22-2 therefore have different, unique elliptical footprints. Subpixel 82-R1 has first elliptical footprint whereas subpixel 82-R2 has a second, different elliptical footprint. The red subpixels in pixels 22-1 and 22-2 therefore have different, unique elliptical footprints.

Each elliptical footprint in FIG. 12 may be characterized by a first radius R1 through center 98, a second radius R2 through center 98, and a rotation angle 96. Radius R1 and radius R2 characterize the size and shape of the ellipse. Rotation angle 96 characterizes the rotation of the ellipse relative to a reference direction such as the Y-axis. Radius R1, radius R2, and rotation angle 96 may be different for subpixel 82-G2 than for subpixel 82-G1. Additionally, the relative position of the center of the subpixel may be different for subpixel 82-G1 than for subpixel 82-G2. In other words, the position of the center of the subpixel within the XY-plane may be adjusted between different pixels. This may cause the center-to-center pitch between subpixels of different colors to vary between pixels. For example, the separation 100-1 between the centers of subpixels 82-B1 and 82-R1 in pixel 22-1 may be different than the separation 100-2 between the centers of subpixels 82-B2 and 82-R2 in pixel 22-2.

In general, any properties associated with the elliptical footprint may be changed between pixels to increase randomization within the display and mitigate diffraction artifacts. For example, the green subpixels may have at least 2 unique elliptical shapes (e.g., R1 and R2 magnitudes) across the display, at least 4 unique elliptical shapes across the display, at least 8 unique elliptical shapes across the display, at least 16 unique elliptical shapes across the display, at least 32 unique elliptical shapes across the display, etc. Instead or in addition, the green subpixels may have at least 2 unique angles of rotation (e.g., magnitude of angle 96) across the display, at least 4 unique angles of rotation across the display, at least 8 unique angles of rotation across the display, at least 16 unique angles of rotation across the display, at least 32 unique angles of rotation across the display, etc. Instead or in addition, the green subpixels may have at least 2 unique relative center positions across the display, at least 4 unique relative center positions across the display, at least 8 unique relative center positions across the display, at least 16 unique relative center positions across the display, at least 32 unique relative center positions across the display, etc. The relative center positions may be measured as x and y coordinates of the center of a subpixel relative to a boundary of the pixel that includes that subpixel (e.g., the dashed lines in FIG. 12).

The red subpixels may have at least 2 unique elliptical shapes (e.g., R1 and R2 magnitudes) across the display, at least 4 unique elliptical shapes across the display, at least 8 unique elliptical shapes across the display, at least 16 unique elliptical shapes across the display, at least 32 unique elliptical shapes across the display, etc. Instead or in addition, the red subpixels may have at least 2 unique angles of rotation (e.g., magnitude of angle 96) across the display, at least 4 unique angles of rotation across the display, at least 8 unique angles of rotation across the display, at least 16 unique angles of rotation across the display, at least 32 unique angles of rotation across the display, etc. Instead or in addition, the red subpixels may have at least 2 unique relative center positions across the display, at least 4 unique relative center positions across the display, at least 8 unique relative center positions across the display, at least 16 unique relative center positions across the display, at least 32 unique relative center positions across the display, etc. The relative center positions may be measured as x and y coordinates of the center of a subpixel relative to a boundary of the pixel that includes that subpixel (e.g., the dashed lines in FIG. 12).

The blue subpixels may have at least 2 unique elliptical shapes (e.g., R1 and R2 magnitudes) across the display, at least 4 unique elliptical shapes across the display, at least 8 unique elliptical shapes across the display, at least 16 unique elliptical shapes across the display, at least 32 unique elliptical shapes across the display, etc. Instead or in addition, the blue subpixels may have at least 2 unique angles of rotation (e.g., magnitude of angle 96) across the display, at least 4 unique angles of rotation across the display, at least 8 unique angles of rotation across the display, at least 16 unique angles of rotation across the display, at least 32 unique angles of rotation across the display, etc. Instead or in addition, the blue subpixels may have at least 2 unique relative center positions across the display, at least 4 unique relative center positions across the display, at least 8 unique relative center positions across the display, at least 16 unique relative center positions across the display, at least 32 unique relative center positions across the display, etc. The relative center positions may be measured as x and y coordinates of the center of a subpixel relative to a boundary of the pixel that includes that subpixel (e.g., the dashed lines in FIG. 12).

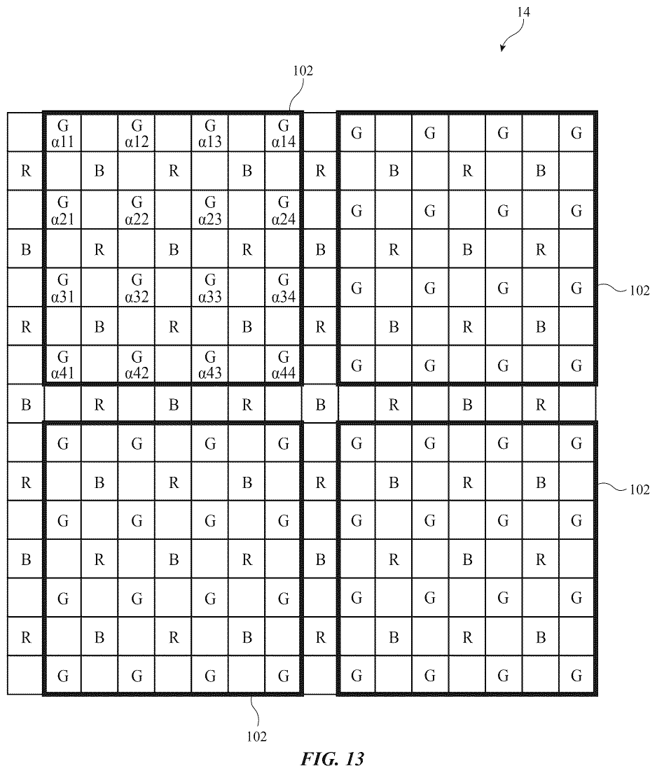

Varying some of the properties of the footprints of the subpixels may mitigate diffractive artifacts associated with display 14. However, additional variance in the properties of the footprints of the subpixels may cause increased manufacturing cost and complexity. To mitigate manufacturing cost and complexity, display 14 may include a repeating unit cell of pixels. Within the unit cell, the properties of the subpixels may vary (e.g., there may be subpixels with elliptical footprints having different angles of rotations, shapes, center positions, etc.). However, the unit cell may be repeated across the display. Examples of unit cells are shown in FIGS. 13-15.

FIGS. 13-15 are top views of illustrative displays with emissive subpixels having repeated unit cells. In FIGS. 13-15, the subpixels are arranged in rows and columns. In FIGS. 13-15, green subpixels are labeled G, red subpixels are labeled R, and blue subpixels are labeled B. Every other row of emissive subpixels includes only green subpixels (see the topmost row of FIG. 13). Every other row of emissive subpixels includes alternating red and blue subpixels (see the 2^{nd}-from-top row of FIG. 13). Similarly, every other column of emissive subpixels includes only green subpixels (see the 2^{nd}-from-left column of FIG. 13). Every other column of emissive subpixels includes alternating red and blue subpixels (see the leftmost column in FIG. 13). For simplicity of the drawing, the subpixels are shown schematically as squares in FIGS. 13-15. However, it should be understood that each subpixel may have an elliptical shape as shown in FIG. 12.

The footprints of a particular color subpixel will first be examined in connection with FIGS. 13-15. In particular, FIGS. 13-15 highlight the footprints of the green subpixels in displays 14. In the example of FIG. 13, there is a 4×4 repeating unit 102 that is repeated across the display. For each instance of repeating unit 102 (sometimes referred to as a unit cell), the layout, sizes, and shapes of the green subpixels are the same. However, the layout, sizes, and shapes of the green subpixels may vary within the unit cell.

In the example of FIG. 13, each green subpixel in unit cell 102 has a unique rotation angle 96 (sometimes referred to simply as angle). The green emissive subpixel in the first row and first column of green emissive subpixels in unit cell 102 has an angle α11, the green emissive subpixel in the first row and second column of green emissive subpixels in unit cell 102 has an angle α12, the green emissive subpixel in the first row and third column of green emissive subpixels in unit cell 102 has an angle α13, the green emissive subpixel in the first row and fourth column of green emissive subpixels in unit cell 102 has an angle α14, the green emissive subpixel in the second row and first column of green emissive subpixels in unit cell 102 has an angle α21, etc. Each one of angles α11, α12, α13, α14, α21, α22, α23, α24, α31, α32, α33, α34, α41, α42, α43, and α44 may have a unique magnitude.

In one possible arrangement, the magnitudes of angles α11, α12, α13, α14, α21, α22, α23, α24, α31, α32, α33, α34, α41, α42, α43, and α44 are selected randomly. In another possible arrangement, the magnitudes of angles α11, α12, α13, α14, α21, α22, α23, α24, α31, α32, α33, α34, α41, α42, α43, and α44 are evenly distributed between 0 degrees and 180 degrees. As an example, the 16 magnitudes for α11, α12, α13, α14, α21, α22, α23, α24, α31, α32, α33, α34, α41, α42, α43, and α44 may include 11.25 degrees, 22.5 degrees, 33.75 degrees, 45 degrees, 56.25 degrees, 67.5 degrees, 78.75 degrees, 90 degrees, 101.25 degrees, 112.5 degrees, 123.75 degrees, 135 degrees, 146.25 degrees, 157.5 degrees, 168.75 degrees, and 180 degrees. In other words, in a sorted list of the magnitudes of the angles, each angle is separated from the adjacent angles by a difference of 180/16 degrees (i.e., 11.25 degrees). These 16 magnitudes may be randomly assigned to the 16 positions of the green subpixels in unit cell 102. Evenly distributing the angles between 0 and 180 degrees may mitigate the visibility of the repeating units across the display.

Unit cell 102 in FIG. 13 therefore includes 16 green subpixels in a 4×4 grid. The 16 green subpixels each have a unique rotation magnitude. Since the unit cell is repeated across the display, there are 16 unique rotation magnitudes for the green subpixels across display 14 in FIG. 13.

In the example of FIG. 14, each unit cell 102 has two types of repeating subunits 104. In particular, the unit cell includes subunits 104-1 and subunits 104-2. For each instance of repeating unit 102, the layout, sizes, and shapes of the green subpixels are the same. However, the layout, sizes, and shapes of the green subpixels may vary within the unit cell. For each instance of subunit 104-1, the layout, sizes, and shapes of the green subpixels are the same. However, the layout, sizes, and shapes of the green subpixels may vary within the subunit. For each instance of subunit 104-2, the layout, sizes, and shapes of the green subpixels are the same. However, the layout, sizes, and shapes of the green subpixels may vary within the subunit.

In particular, each green subpixel in subunit 104-1 has a unique rotation angle 96. The green emissive subpixel in the first row and first column of green emissive subpixels in subunit 104-1 has an angle α1, the green emissive subpixel in the first row and second column of green emissive subpixels in subunit 104-1 has an angle α2, the green emissive subpixel in the second row and first column of green emissive subpixels in subunit 104-1 has an angle α3, the green emissive subpixel in the second row and second column of green emissive subpixels in subunit 104-1 has an angle α4. Each green subpixel in subunit 104-2 has a unique rotation angle 96. The green emissive subpixel in the first row and first column of green emissive subpixels in subunit 104-2 has an angle θ1, the green emissive subpixel in the first row and second column of green emissive subpixels in subunit 104-2 has an angle θ2, the green emissive subpixel in the second row and first column of green emissive subpixels in subunit 104-2 has an angle θ3, the green emissive subpixel in the second row and second column of green emissive subpixels in subunit 104-2 has an angle θ4.

In one possible arrangement, the magnitudes of angles α1, α2, α3, α4, θ1, θ2, θ3, and θ4, are selected randomly. In another possible arrangement, the magnitudes of angles α1, α2, α3, α4, θ1, θ2, θ3, and θ4 are evenly distributed between 0 degrees and 180 degrees. As an example, the 8 magnitudes for α1, α2, α3, α4, θ1, θ2, θ3, and θ4 may include 22.5 degrees, 45 degrees, 67.5 degrees, 90 degrees, 112.5 degrees, 135 degrees, 157.5 degrees, and 180 degrees. In other words, in a sorted list of the magnitudes of the angles, each angle is separated from the adjacent angles by a difference of 180/8 degrees (i.e., 22.5 degrees). These 8 magnitudes may be randomly assigned to the 8 positions of the green subpixels in subunits 104-1 and 104-2.

Unit cell 102 in FIG. 14 therefore includes a 2×2 grid of subunits. The 2×2 grid of subunits includes two different types of subunits. Each type of subunit includes a 2×2 grid of green subpixels. There are therefore 8 unique rotation magnitudes for 16 green subpixels in each unit cell 102. Since the unit cell is repeated across the display, there are 8 unique rotation magnitudes for the green subpixels across display 14 in FIG. 14.

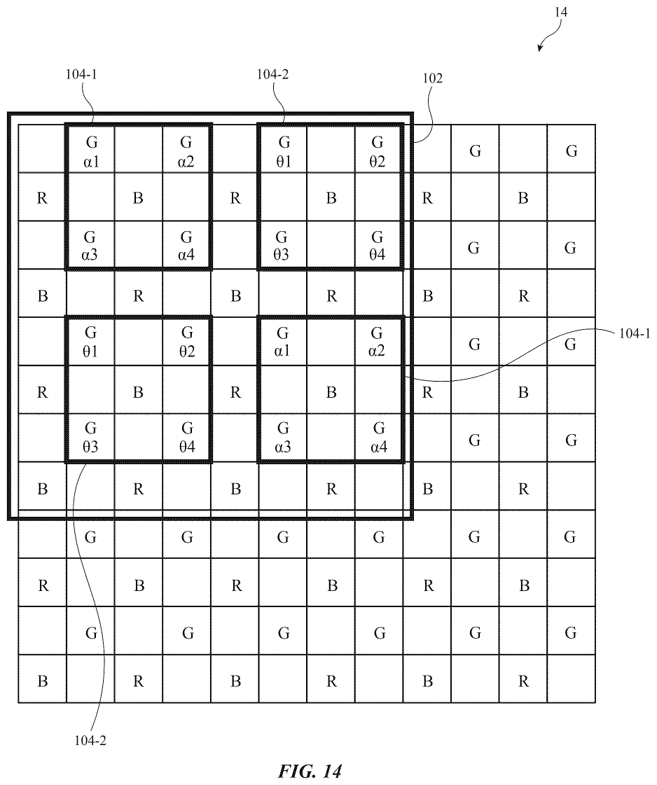

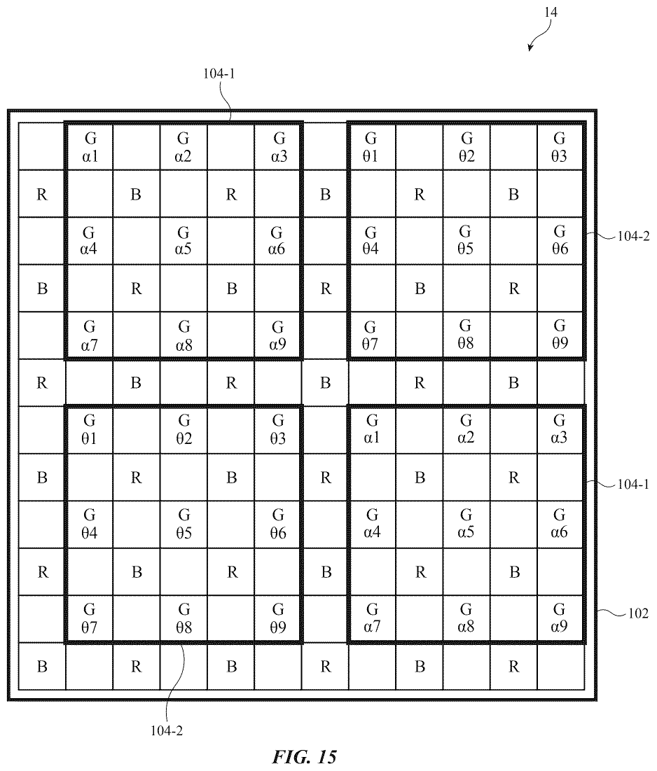

The example in FIG. 14 of each subunit including a 2×2 grid of green subpixels is merely illustrative. In another possible arrangement, shown in FIG. 15, each subunit may include a 3×3 grid of green subpixels.

The green emissive subpixel in the first row and first column of green emissive subpixels in subunit 104-1 has an angle α1, the green emissive subpixel in the first row and second column of green emissive subpixels in subunit 104-1 has an angle α2, the green emissive subpixel in the first row and third column of green emissive subpixels in subunit 104-1 has an angle α3, the green emissive subpixel in the second row and first column of green emissive subpixels in subunit 104-1 has an angle α4, etc. Each green subpixel in subunit 104-2 has a unique rotation angle 96. The green emissive subpixel in the first row and first column of green emissive subpixels in subunit 104-2 has an angle θ1, the green emissive subpixel in the first row and second column of green emissive subpixels in subunit 104-2 has an angle θ2, the green emissive subpixel in the first row and third column of green emissive subpixels in subunit 104-2 has an angle θ3, the green emissive subpixel in the second row and first column of green emissive subpixels in subunit 104-2 has an angle θ4, etc.

In one possible arrangement, the magnitudes of angles α1, α2, α3, α4, α5, α6, α7, α8, α9, θ1, θ2, θ3, θ4, θ5, θ6, θ7, θ8, and θ9 are selected randomly. In another possible arrangement, the magnitudes of angles α1, α2, α3, α4, α5, α6, α7, α8, α9, θ1, θ2, θ3, θ4, θ5, θ6, θ7, θ8, and θ9 are evenly distributed between 0 degrees and 180 degrees. As an example, the 18 magnitudes for α1, α2, α3, α4, α5, α6, α7, α8, α9, θ1, θ2, θ3, θ4, θ5, θ6, θ7, θ8, and θ9 may include 10 degrees, 20 degrees, 30 degrees, 40 degrees, 50 degrees, 60 degrees, 70 degrees, 80 degrees, 90 degrees, 100 degrees, 110 degrees, 120 degrees, 130 degrees, 140 degrees, 150 degrees, 160 degrees, 170 degrees, and 180 degrees. In other words, in a sorted list of the magnitudes of the angles, each angle is separated from the adjacent angles by a difference of 180/18 degrees (i.e., 10 degrees). These 18 magnitudes may be randomly assigned to the 18 positions of the green subpixels in subunits 104-1 and 104-2.

Unit cell 102 in FIG. 15 therefore includes a 2×2 grid of subunits. The 2×2 grid of subunits includes two different types of subunits. Each type of subunit includes a 3×3 grid of green subpixels. There are therefore 18 unique rotation magnitudes for 36 green subpixels in each unit cell 102. Since the unit cell is repeated across the display, there are 18 unique rotation magnitudes for the green subpixels across display 14 in FIG. 15.

In some arrangements, the elliptical shapes (e.g., R1 and R2) for the subpixels in FIGS. 13-15 may be varied in addition to the rotation angles. Alternatively, the elliptical shapes for each color may be fixed. As one example, R1 and R2 may be constant across the unit cell. R1 and R2 may therefore have a fixed ratio. The fixed ratio may be equal to 0.8, between 0.75 and 0.85, less than 0.9, greater than 0.7, etc.

FIGS. 13-15 have been described in relation to the rotation angles of the green subpixels. The blue and red subpixels may have corresponding unit cells that are independent of the unit cells associated with the green subpixels. Alternatively, the unit cells for the green cells may also include unique rotation angles for the red and blue subpixels. The rotation angles for the red and blue subpixels may be equal to the rotation angles for the green subpixels or different from the rotation angles for the green subpixels.

The region on display 14 where the display pixels 22 are formed may sometimes be referred to herein as the active area. Electronic device 10 has an external housing with a peripheral edge. The region surrounding the active area and within the peripheral edge of device 10 is the border region. Images can only be displayed to a user of the device in the active region. It is generally desirable to minimize the border region of device 10. For example, device 10 may be provided with a full-face display 14 that extends across the entire front face of the device. If desired, display 14 may also wrap around over the edge of the front face so that at least part of the lateral edges or at least part of the back surface of device 10 is used for display purposes.

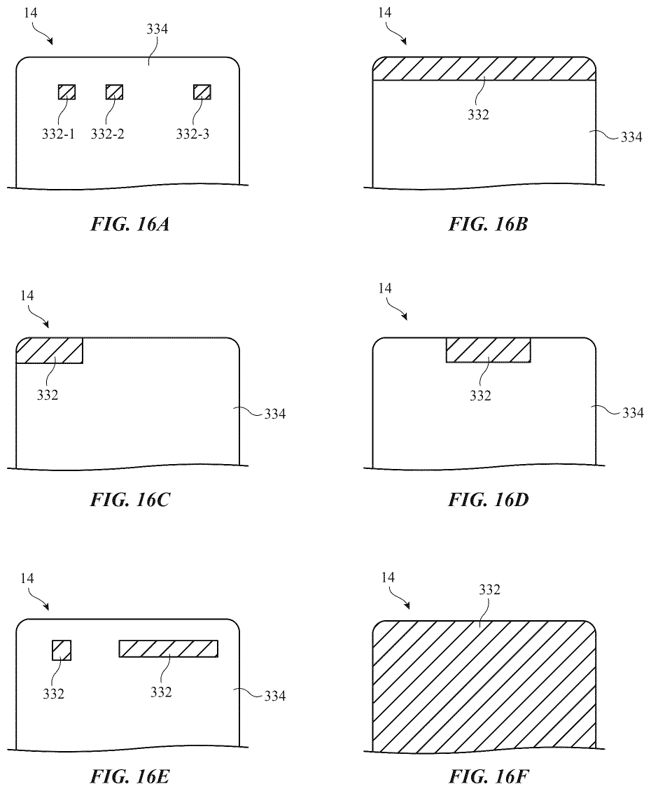

Device 10 may include a sensor mounted behind display 14 (e.g., behind the active area of the display). FIGS. 16A-16F are top views of illustrative displays 14 with a sensor mounted behind the active area (AA) of the display. In some cases, the majority of display 14 may have the same layout. The pixel layout used for the majority of the display may sometimes be referred to as a base layout, majority layout, or normal layout. Portions of display 14 that overlap an input-output component such as a sensor may be modified relative to the base layout. In particular, the portions of display 14 that overlap an input-output component may be modified to have a higher transparency than the base layout.

In general, the display may be modified to have an increased transparency in any region(s) of display 14. FIGS. 16A-16F are front views showing how display 14 may have one or more locally modified regions in which the display is modified to increase transparency. The example of FIG. 16A illustrates various locally modified regions 332 physically separated from one another (i.e., the various locally modified regions 332 are non-continuous) by normal display region 334. The locally modified regions 332 may have some modification relative to normal display region 334 that increase transparency. These regions may therefore sometimes be referred to as increased-transparency regions 332, high-transparency regions 332, etc. The normal display region 334 may sometimes be referred to as low-transparency region 334, opaque region 334, etc.

The three locally modified regions 332-1, 332-2, and 332-3 in FIG. 16A might for example correspond to three different sensors formed underneath display 14 (with one sensor per locally modified region). Any portion of the display that is within the field-of-view of an underlying sensor may be modified to increase transparency.

The example of FIG. 16B illustrates a continuous locally modified region 332 formed along the top border of display 14, which might be suitable when there are many optical sensors positioned near the top edge of device 10. The example of FIG. 16C illustrates a locally modified region 332 formed at a corner of display 14 (e.g., a rounded corner area of the display). In some arrangements, the corner of display 14 in which locally modified region 332 is located may be a rounded corner (as in FIG. 16C) or a corner having a substantially 90° corner. The example of FIG. 16D illustrates a locally modified region 332 formed only in the center portion along the top edge of device 10 (i.e., the locally modified region covers a recessed notch area in the display). FIG. 16E illustrates another example in which locally modified regions 332 can have different shapes and sizes. FIG. 16F illustrates yet another suitable example in which the locally modified region covers the entire display surface. In other words, the entire display may have a high transparency. These examples are merely illustrative and are not intended to limit the scope of the present embodiments. If desired, any one or more portions of the display overlapping with optically based sensors or other sub-display electrical components may be designated as a locally modified region to increase transparency.

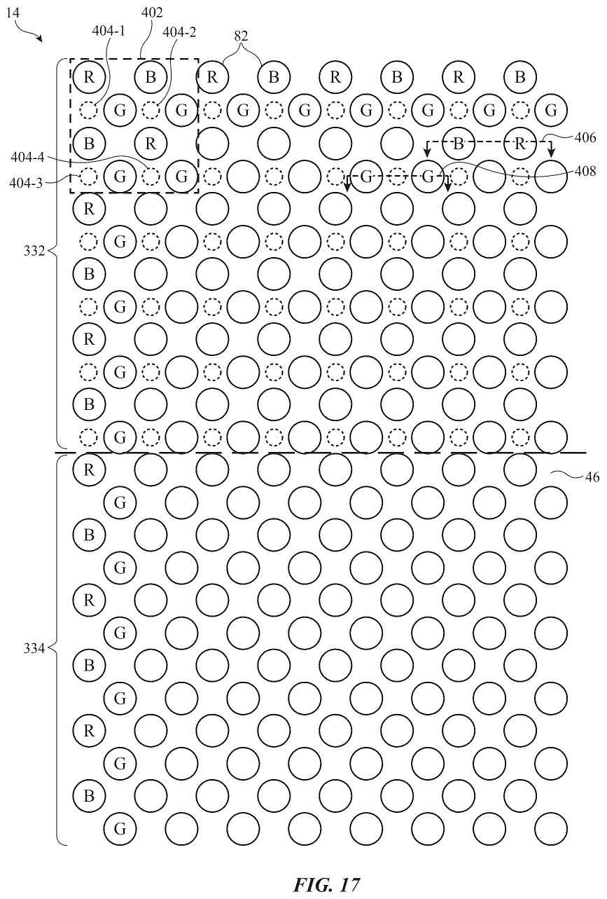

FIG. 17 is a top view of an illustrative display with a locally modified region 332. FIG. 17 shows both locally modified region 332 and normal display region 334. In both locally modified region 332 and normal display region 334, the layout of subpixels 82 is the same. In FIG. 17, green subpixels are labeled G, red subpixels are labeled R, and blue subpixels are labeled B. Similar to as in FIGS. 13-15, every other row of emissive subpixels includes only green subpixels (see the 2^{nd}-from-top row of FIG. 17). Every other row of emissive subpixels includes alternating red and blue subpixels (see the top row of FIG. 17). Every other column of emissive subpixels includes only green subpixels (see the 2^{nd}-from-left column of FIG. 17). Every other column of emissive subpixels includes alternating red and blue subpixels (see the leftmost column in FIG. 17). FIG. 17 shows how the emissive subpixels may be arranged in unit cells 402. Each unit cell in FIG. 17 includes four green subpixels, two red subpixels, and two blue subpixels.

The area between adjacent subpixels may be covered by black matrix 46. In normal display region 334, black matrix 46 is uninterrupted between adjacent subpixels 82. Each unit cell 402 in normal display region 334 therefore has no openings in the black matrix between subpixels.

In locally modified region 332, however, there are openings 404 between some of the subpixels 82. In the example of FIG. 17, each unit cell 402 in locally modified region 332 has four openings 404 in the black matrix between subpixels. A first opening 404-1 is positioned in the second row and first column of subpixels, a second opening 404-2 is positioned in the second row and third column of subpixels, a third opening 404-3 is positioned in the fourth row and first column of subpixels, and a fourth opening 404-4 is positioned in the fourth row and third column of subpixels. This arrangement for the openings is merely illustrative and in general the openings may have any desired positions within the unit cell in locally modified region 332.

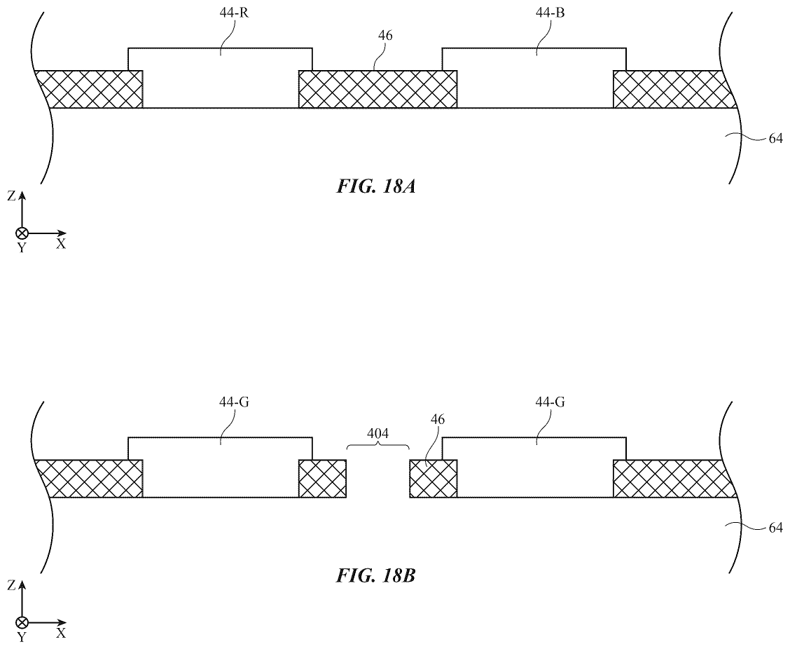

FIG. 18A is a cross-sectional side view taken along line 406 of FIG. 17 (between two adjacent subpixels without an intervening black matrix opening). FIG. 18B is a cross-sectional side view taken along line 408 of FIG. 17 (between two adjacent subpixels with an intervening black matrix opening). As shown in FIG. 18A, black matrix 46 may extend continuously between two adjacent color filter elements when there is no black matrix opening. FIG. 18B shows how opening 404 may extend completely through black matrix layer 46. The opening may allow light to pass through the black matrix to an underlying sensor. If desired, one or more additional components that vertically overlap opening 404 (e.g., pixel definition layer 42, cathode 40, dark metal layer 58, substrate 26, etc.) may have corresponding openings aligned with opening 404 in the Z-direction.

In the example of FIG. 17, the unit cells in locally modified region 332 with 4 openings are directly adjacent to the unit cells in normal region 334 with 0 openings. This example is merely illustrative. To smooth the visibility of the boundary between locally modified region 332 and normal region 334, locally modified region 332 may include a transition region.

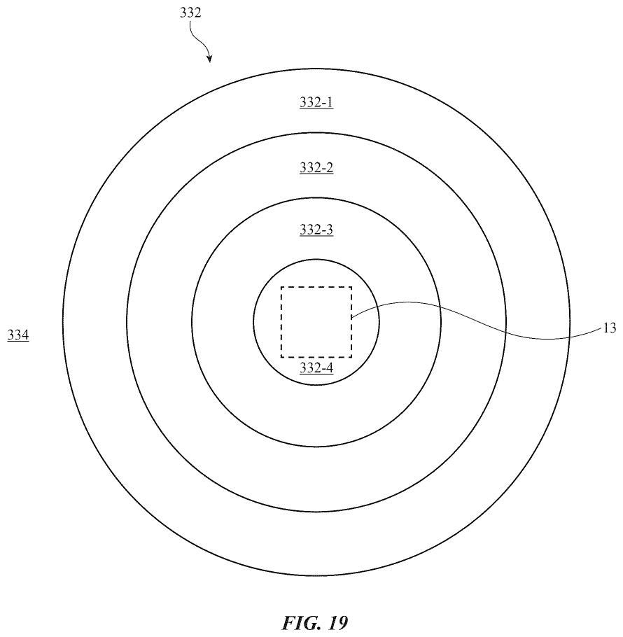

FIG. 19 is a top view of an illustrative display with a locally modified region 332 that includes a transition region. Locally modified region 332 may overlap sensor 13. The sensors in electronic device 10 may include force sensors (e.g., strain gauges, capacitive force sensors, resistive force sensors, etc.), audio sensors such as microphones, touch and/or proximity sensors such as capacitive sensors (e.g., a two-dimensional capacitive touch sensor associated with a display and/or a touch sensor that forms a button, trackpad, or other input device not associated with a display), and other sensors. The sensors may include optical sensors such as optical sensors that emit and detect light (e.g., optical proximity sensors such as transreflective optical proximity structures), ultrasonic sensors, and/or other touch and/or proximity sensors, monochromatic and color ambient light sensors, image sensors, fingerprint sensors, temperature sensors, proximity sensors and other sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors, radio-frequency sensors, depth sensors (e.g., structured light sensors and/or depth sensors based on stereo imaging devices), optical sensors such as self-mixing sensors and light detection and ranging (lidar) sensors that gather time-of-flight measurements, humidity sensors, moisture sensors, gaze tracking sensors, and/or other sensors. Sensor 13 in FIG. 19 may be configured to detect and/or emit light.

As shown in FIG. 19, locally modified region 332 may include a first portion 332-1, a second portion 332-2, a third portion 332-3, and a fourth portion 332-4. The fourth portion 332-4 overlaps sensor 13. The first, second, and third portions may serve as a transition region between portion 332-4 and normal region 334 to mitigate the visibility of a boundary between normal region 334 and locally modified region 332.

As an example, each unit cell in portion 332-4 may include 4 openings (as in region 332 in FIG. 17) whereas each unit cell in portion 334 may include 0 openings (as in region 334 in FIG. 17). To transition between these two regions, locally modified region 332-1 has 1 opening in each unit cell, locally modified region 332-2 has 2 openings in each unit cell, and locally modified region 332-3 has 3 openings in each unit cell.

The example in FIG. 19 of a 4-step transition between normal region 334 and the locally modified region 332-4 over sensor 13 is merely illustrative. In general, there may be any desired number of steps between normal region 334 and the locally modified region over sensor 13 (e.g., 2, 3, 4, 5, more than 5, more than 6, etc.).

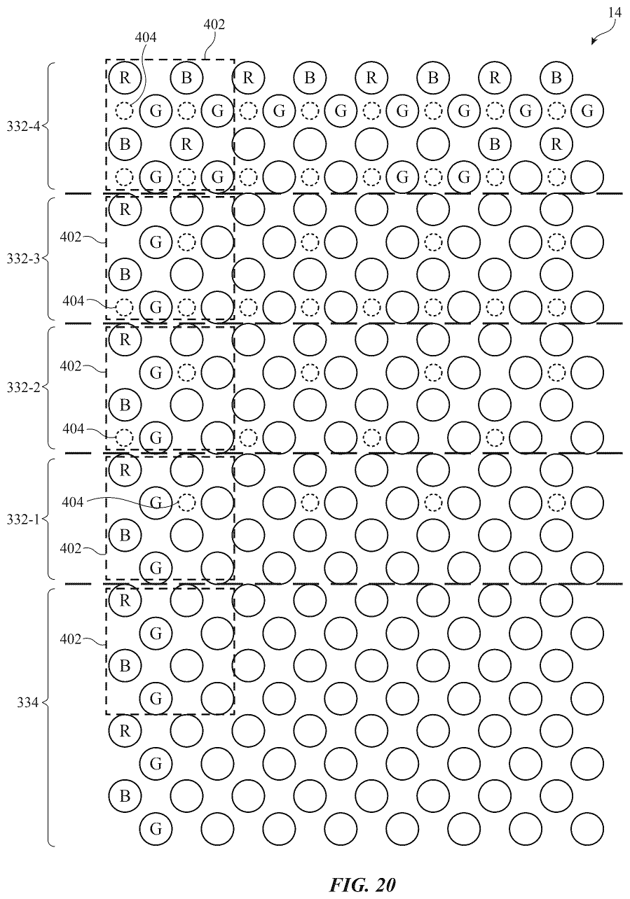

FIG. 20 is a top view of the display of FIG. 19. FIG. 20 shows how each unit cell 402 in normal region 334 has 0 openings 404, each unit cell 402 in locally modified region 332-1 has 1 opening 404, each unit cell 402 in locally modified region 332-2 has 2 openings 404, each unit cell 402 in locally modified region 332-3 has 3 openings 404, and each unit cell 402 in locally modified region 332-4 has 4 openings 404.

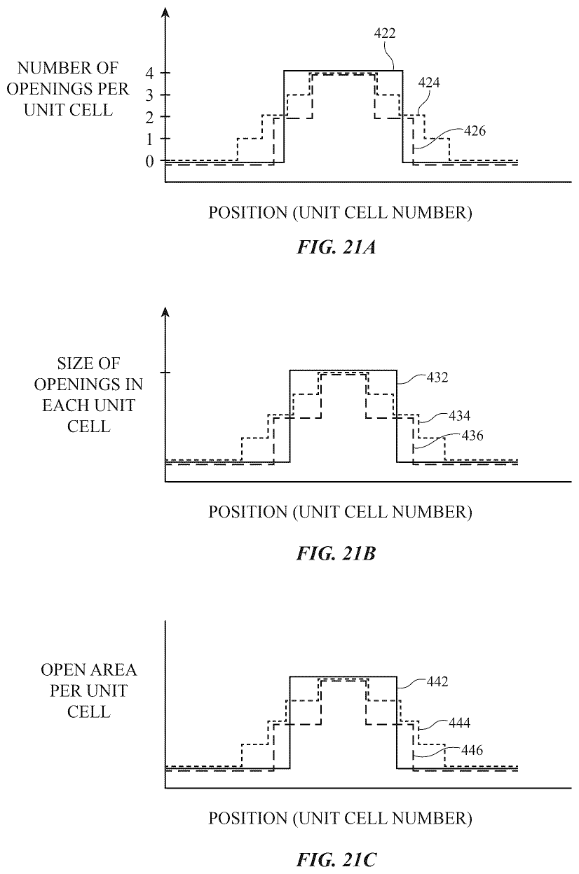

FIG. 21A is a graph of the number of openings per unit cell as a function of position across the display (in units of unit cell number). Profile 422 shows the example where locally modified region 332 does not include a transition region. There is a single change in the number of openings per unit cell between the normal display region 334 and the locally modified region 332 (as in FIG. 17). Profile 424 shows the example where there are four changes in the number of openings per unit cell between the normal display region 334 and locally modified region 332-4 (as in FIGS. 19 and 20). Profile 426 shows an alternate example where there are two changes in the number of openings per unit cell between the normal display region 334 and the locally modified region 332. In general, the profile of the number of openings per unit cell as a function of position may have any desired number of steps, each step may include any desired number of unit cells, etc.

In the example of FIGS. 19, 20, and 21A, the number of openings in each unit cell changes across the display and the size of the openings is constant. This example is merely illustrative. Instead or in addition to varying the number of openings in each unit cell, the size of the openings in each unit cell may be varied.

FIG. 21B is a graph of the size of the openings in each unit cell as a function of position across the display (in units of unit cell number). Profile 432 shows the example where locally modified region 332 does not include a transition region. There is a single change in the size of the openings in each unit cell between the normal display region 334 (where there are no openings and the opening size may be considered equal to 0) and the locally modified region 332 (as in FIG. 17). Profile 434 shows an example where there are four changes in the size of the openings in each unit cell between the normal display region 334 and locally modified region 332-4. Returning to FIG. 19, locally modified region 332-1 may have four openings per unit cell with each opening having a first size, locally modified region 332-2 may have four openings per unit cell with each opening having a second size that is greater than the first size, locally modified region 332-3 may have four openings per unit cell with each opening having a third size that is greater than the second size, and locally modified region 332-4 may have four openings per unit cell with each opening having a fourth size that is greater than the third size. The size of the openings therefore gradually changes across the display. Profile 436 shows an alternate example where there are two changes in the size of the openings in each unit cell between the normal display region 334 and the locally modified region 332. In general, the profile of the size of the openings in each unit cell as a function of position may have any desired number of steps, each step may include any desired number of unit cells, etc.

Both varying the number of openings per unit cell and varying the size of the openings in each unit cell may cause variance in the total open area in each unit cell. The total open area in each unit cell refers to the sum of the surface area of the openings in each unit cell. Ultimately, gradually changing the total open area per unit cell as a function of position may mitigate the visibility of a border between region 332 and region 334.

FIG. 21C is a graph of the open area per unit cell as a function of position across the display (in units of unit cell number). Profile 442 shows the example where locally modified region 332 does not include a transition region. There is a single change in the open area per unit cell between the normal display region 334 and the locally modified region 332 (as in FIG. 17). Profile 444 shows the example where there are four changes in the open area per unit cell between the normal display region 334 and locally modified region 332-4 (as in FIGS. 19 and 20). Profile 426 shows an alternate example where there are two changes in the open area per unit cell between the normal display region 334 and the locally modified region 332. In general, the profile of the open area per unit cell as a function of position may have any desired number of steps, each step may include any desired number of unit cells, etc. The number of openings per unit cell and/or the size of the openings in the unit cell may be varied to create the target open area per unit cell profile.

In the examples herein, each subpixel 82 may have a first opening in pixel definition layer 42 that defines a light-emitting area for that subpixel. The subpixel may also have a second opening in black matrix 46 that overlaps the first opening. The second opening may have a larger surface area (footprint) than the first opening.

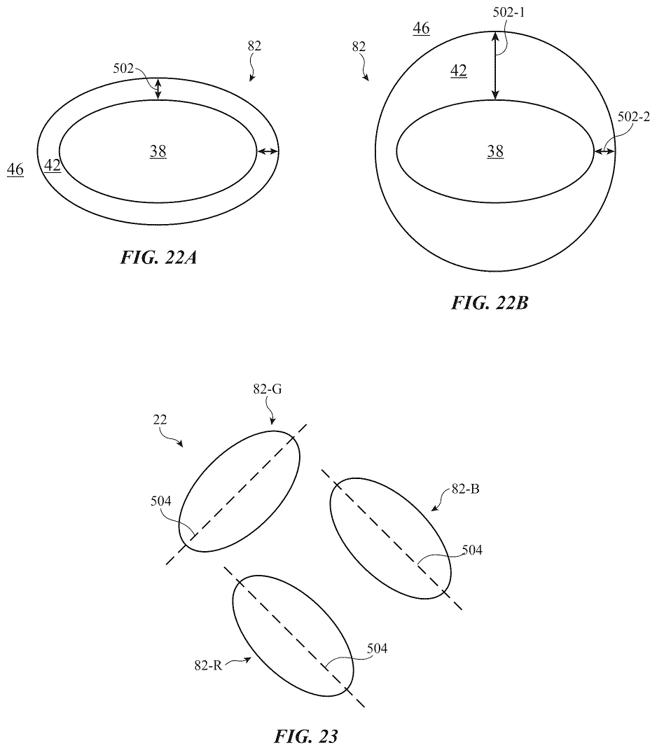

FIG. 22A is a top view of an illustrative subpixel with a uniform black matrix pullback relative to pixel definition layer 42. As shown in FIG. 22A, pixel definition layer 42 may have an opening that defines a light-emitting aperture that is filled with OLED layers 38. Black matrix 46 may overlap pixel definition layer 42. Black matrix 46 has an edge that defines a second opening that overlaps the first opening. The edge of black matrix 46 is separated from the edge of pixel definition layer 42 by a distance 502 (sometimes referred to as pullback distance 502, black matrix pullback distance 502, etc.).

FIGS. 22A and 22B both show examples where subpixel 82 has an elliptical shape (as in FIG. 12). In FIG. 22A, the black matrix pullback distance 502 is uniform around the periphery of the subpixel. Alternatively, as shown in FIG. 22B, the black matrix pullback distance 502 may vary around the periphery of the subpixel. As shown in FIG. 22B, the pullback distance may have a maximum magnitude 502-1 in a direction that is parallel to the minor axis of the elliptical subpixel and a minimum magnitude 502-2 in a direction that is parallel to the major axis of the elliptical subpixel. Varying the pullback distance as in FIG. 22B may mitigate the visibility of repeating units 102 shown in FIGS. 13-15.

Instead or in addition to using the varying pullback distance of FIG. 22B, adjustments to the cathode layer may be used to mitigate the visibility of repeating units 102. In particular, reflections off portions of the cathode on tapered surfaces 66 of pixel definition layer 42 may cause visible artifacts in display 14. The cathode may therefore be selectively removed in regions overlapping pixel definition layer 42. Referring to FIG. 6, cathode 40 may be selectively removed in region 602 over pixel definition layer 42. The cathode is therefore removed from tapered surface 66 of pixel definition layer 42. Removing the cathode reduces reflections off tapered surface 66 that may otherwise cause visible artifacts. Instead or in addition, the taper angle of pixel definition layer 42 may be between 41 and 49 degrees (e.g., between 44 and 46 degrees, 45 degrees, etc.) to prevent any reflections off the tapered surface from exiting the display due to total internal reflection (TIR). Instead or in addition, the cathode may be covered by an opaque material as shown by dark metal layer 58 in FIG. 7. Instead or in addition, the cathode may be formed using a transparent conductive oxide (TCO) material to mitigate reflectance off the cathode.

Another option for mitigating the visibility of repeating units 102 is shown in FIG. 23. As shown in FIG. 23, each pixel may include a green elliptical subpixel 82-G, a blue elliptical subpixel 82-B, and a red elliptical subpixel 82-R. To mitigate the visibility of repeating units across the display, the major axes 504 of the blue and red subpixels may be parallel and the major axis of the green subpixel is orthogonal to the major axes of the blue and red subpixels. This relationship may be true for every pixel in the display, even when the major axes of subpixels of the same color are at different angles in different pixels.

A single display may optionally have one or more of the features described herein.

The foregoing is merely illustrative and various modifications can be made by those skilled in the art without departing from the scope and spirit of the described embodiments. The foregoing embodiments may be implemented individually or in any combination.

What is claimed is:

1. A display comprising:
a substrate;
an array of light-emitting diodes on the substrate;
a black matrix that is formed over the array of light-emitting diodes and that defines a plurality of openings;
a plurality of color filter elements, wherein each one of the plurality of color filer elements is formed in a respective opening of the plurality of openings; and
an opaque pixel definition layer that defines light-emitting apertures for the array of light-emitting diodes, wherein the opaque pixel definition layer has tapered surfaces, wherein the opaque pixel definition layer has a first optical density, and wherein the black matrix has a portion with a second optical density that is greater than the first optical density.

2. The display defined in claim 1, wherein the tapered surfaces of the opaque pixel definition layer have a taper angle of less than 35 degrees.

3. The display defined in claim 1, wherein the first optical density is less than 0.5 μm⁻¹ and wherein the second optical density is greater than 1.3 μm⁻¹.

4. The display defined in claim 1, wherein a difference between the first and second optical densities is greater than 0.8 μm⁻¹.

5. The display defined in claim 1, wherein the array of light-emitting diodes comprises a cathode and wherein the cathode comprises transparent conductive oxide.

6. The display defined in claim 1, wherein the array of light-emitting diodes comprises a cathode and wherein the display further comprises:
transparent metal patterning layers that overlap the light-emitting apertures for the array of light-emitting diodes; and
a metal layer that has openings aligned with the transparent metal patterning layers, wherein the cathode is interposed between the opaque pixel definition layer and the metal layer.

7. The display defined in claim 6, wherein the metal layer has additional tapered surfaces that conform to the transparent metal patterning layers.

8. The display defined in claim 1, wherein the black matrix has an additional portion with a third optical density that is less than the second optical density.

9. The display defined in claim 8, wherein the additional portion of the black matrix has a larger footprint than the portion of the black matrix.

10. The display defined in claim 1, further comprising:
a plurality of microlenses, wherein each color filter element of the plurality of color filter elements conforms to at least one of the plurality of microlenses.

11. The display defined in claim 10, wherein a given color filter element of the plurality of color filter elements overlaps and conforms to more than one of the plurality of microlenses.

12. The display defined in claim 10, further comprising:
one or more planarization layers interposed between the array of light-emitting diodes and the black matrix, wherein the black matrix, the plurality of color filter elements, and the plurality of microlenses overlap the one or more planarization layers and wherein a given microlens of the plurality of microlenses has a lower refractive index than both the one or more planarization layers and a given color filter element of the plurality of color filter elements that overlaps the given microlens.

13. The display defined in claim 1, wherein the array of light-emitting diodes comprises a light-emitting diode and wherein the light-emitting diode comprises an anode with a concave upper surface.

14. The display defined in claim 13, wherein an opening of the plurality of openings overlaps the anode with the concave upper surface and wherein the opening is a ring-shaped opening.

15. The display defined in claim 1, wherein the array of light-emitting diodes comprises a light-emitting diode and wherein the light-emitting diode comprises an anode with a convex upper surface.

16. A display comprising:
a substrate;
an array of pixels on the substrate, wherein the array of pixels comprises green subpixels, blue subpixels, and red subpixels;
a black matrix that defines elliptical openings for the green subpixels, blue subpixels, and red subpixels; and
a plurality of color filter elements, wherein each one of the plurality of color filer elements is formed in a respective elliptical opening of the elliptical openings, wherein the elliptical openings for the green subpixels have rotation angles that vary within a unit cell that is repeated across the array of pixels, and wherein the rotation angles for the green subpixels within the unit cell are evenly distributed between 0 degrees and 180 degrees.

17. The display defined in claim 16, wherein the unit cell comprises a first repeated subunit with a first subset of the rotation angles and a second repeated subunit with a second subset of the rotation angles.

18. The display defined in claim 16, further comprising:
a pixel definition layer, wherein a first elliptical opening of the elliptical openings is aligned with a second elliptical opening in the pixel definition layer and wherein a separation distance between an edge of the pixel definition layer that defines the second elliptical opening and an edge of the black matrix that defines the first elliptical opening varies around a periphery of the first and second elliptical openings.

19. The display defined in claim 16, wherein each pixel in the array of pixels comprises one elliptical green subpixel characterized by a first major axis, one elliptical red subpixel characterized by a second major axis, and one elliptical blue subpixel characterized by a third major axis, and wherein, for each pixel, the first major axis is orthogonal to the second and third major axes.

20. An electronic device, comprising:
a sensor; and
a display having an array of pixels and a black matrix, wherein the array of pixels comprises subpixels that emit light through the black matrix and wherein the display comprises:
a first portion that overlaps the sensor, wherein the subpixels in the first portion are arranged in a repeated unit cell and wherein the repeated unit cell in the first portion comprises a first number of black matrix openings between adjacent subpixels;
a second portion, wherein the subpixels in the second portion are arranged in the repeated unit cell and wherein the repeated unit cell in the second portion comprises a second number of black matrix openings between adjacent subpixels; and
a third portion that is interposed between the first and second portions, wherein the subpixels in the third portion are arranged in the repeated unit cell, wherein the repeated unit cell in the third portion comprises a third number of black matrix openings between adjacent subpixels, and wherein the third number is between the first number and the second number.

21. The electronic device defined in claim 20, wherein the second number is 0.

22. The electronic device defined in claim 20, wherein the first number of openings comprise openings with a first size and wherein the third number of openings comprise openings with a second size that is different than the first size.
